(19) United States
(12) Patent Application Publication
(10) Pub. No.: US 2008/0315400 A1
(43) Pub. Date: Dec. 25, 2008

(54) MICROELECTROMECHANICAL SYSTEMS DESIGN FEATURE

(75) Inventor: Michael J. Foster, Issaquah, WA (US)

Correspondence Address: HONEYWELL INTERNATIONAL INC.;PATENT SERVICES AB-2B, 101 COLUMBIA ROAD, P.O. BOX 2245, MORRISTOWN, NJ, 07962-2245, US

(73) Assignee: Honeywell International, Inc., Morristown, NJ (US)

(21) Appl. No.: 11/766,939

(22) Filed: Jun. 22, 2007

(51) Int. Cl. H01L 23/48; H01L 21/00

(52) U.S. Cl. 257/701; 438/106; 257/E23.01; 257/E21.001

(57) ABSTRACT

A device for reducing the chance that a microelectromechanical systems (MEMS) device with moving parts will have those parts stick to a glass cover of the MEMS device, and a method for making the device. An example embodiment of the invention includes a MEMS device wafer, a substrate wafer, and a glass cover. The MEMS device wafer includes perforations corresponding to the location(s) of exposed glass on the cover. An example embodiment of a method of the invention includes applying metal layers to a glass cover, perforating a device wafer at locations corresponding to areas of exposed glass on the glass cover, mounting the device wafer to the substrate wafer, and anodically bonding the glass cover to the substrate wafer or to the device wafer.

### BACKGROUND OF THE INVENTION

Microelectromechanical systems (MEMS) devices are often enclosed in part with a cover. The cover functions as a shock cage, dust cover and additional capacitance surfaces. When the cover is made of glass, the glass cover is anodically bonded to a silicon MEMS device wafer. When voltage is applied to bond the upper cover, electric charges accumulate on any exposed glass. The surface of the glass can be covered with a metal layer that is grounded during bonding to avoid the build-up of electric charge, but in order to define separate electrical areas there must be thin lines of open glass on the inner surface of the cover. Electric charges collect on the thin lines of glass. The build-up of charges on exposed glass is a problem, because in the case of MEMS devices with moving parts, the parts may be pulled up by the electrostatic forces and stick to the cover. Mathematically, the relationship can be defined through the sum of the forces on the MEMS device:

$$\sum Forces := - {K}_{Z} \cdot δ + \frac{1}{2} {ɛ}_{0} \cdot \frac{Area}{{( Gap - δ )}^{2}} \cdot {V}_{A}^{2} ;$$

where K_{Z} is the mechanism stiffness, delta is the mechanism deflection, E0 is the permittivity of air, Area is the overlapping area of exposed glass and mechanism wafer silicon, gap is the nominal gap between the glass cover and the mechanism wafer, and Va is the anodic bond voltage.

Increasing the MEMS mechanism stiffness or the gap between the glass cover and the mechanism would reduce the chance of mechanism malfunction, but would also affect the mechanism performance. Decreasing the anodic bond voltage can lead to a weak bond.

### SUMMARY OF THE INVENTION

The present invention provides a device for reducing the electrostatic forces between a mechanism and glass covers during anodic bonding, and for preventing a MEMS device with moving parts from having those parts stick to a glass cover of the MEMS device, as well as a method for making the device. An example embodiment of the invention includes a MEMS device, a substrate wafer, and a glass cover. The MEMS device wafer includes perforations corresponding to the location(s) of exposed glass on the cover. This configuration reduces the amount of electrostatic force experienced by a MEMS device by decreasing the overlapping area between the silicon mechanism and the exposed glass.

An example embodiment of a method of the invention includes applying metal layers to a glass cover, perforating a device wafer at locations corresponding to areas of exposed glass on the glass cover, and anodically bonding the glass cover to the device wafer.

### BRIEF DESCRIPTION OF THE DRAWINGS

Preferred and alternative embodiments of the present invention are described in detail below with reference to the following drawings:

FIG. 1A is a partial cross-section of a side view of an embodiment of a device according to the present invention;

FIG. 1B is a partial cross-section of a side view of an alternate embodiment of a device according to the present invention;

FIG. 1C is a top view of a section of the cover and underlying device of FIG. 1A;

FIG. 1D is a top partial cutaway view of area 1D of FIG. 1C of the cover of FIG. 1A and the underlying mechanism wafer;

FIG. 1E is a side cross-sectional view of the devices of FIGS. 1A and 1B; and

FIG. 2 is a flow diagram of a method according to an embodiment of the present invention.

### DETAILED DESCRIPTION OF THE PREFERRED EMBODIMENT

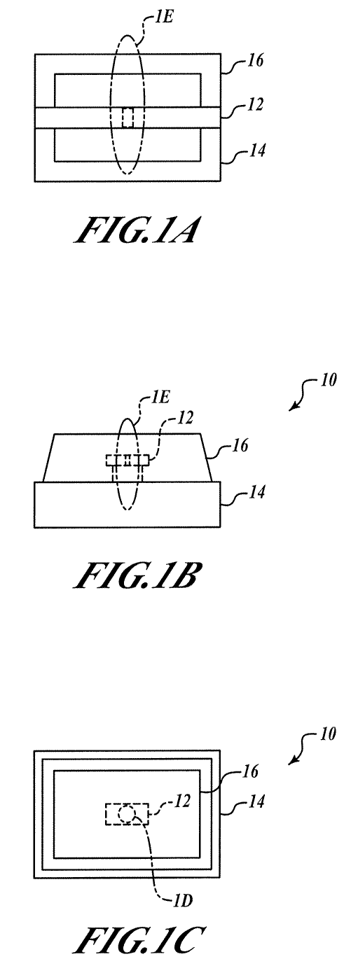

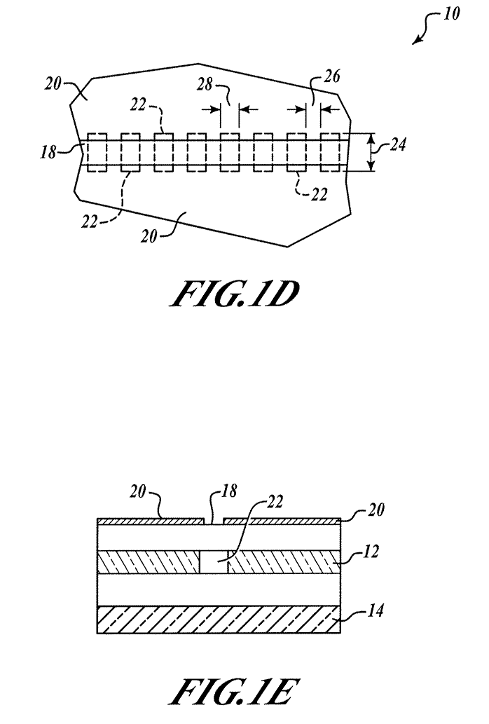

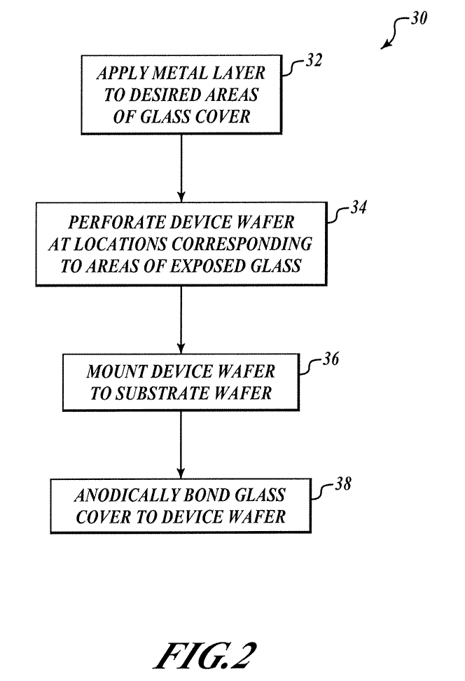

FIGS. 1A and 1B are side views of alternate embodiments of a device 10 according to one embodiment of the present invention, and FIG. 1C is a top view of the embodiment of FIG. 1A. The device 10 includes a MEMS device wafer 12 mounted on a substrate wafer 14. In the embodiment of FIG. 1A, the cover 16 is anodically bonded to the device wafer 12, preferably on a same horizontal plane as the MEMS device (not shown), and the substrate wafer 14 and cover 16 are preferably glass. In FIG. 1B, the cover 16 is anodically bonded to the substrate wafer 14, and the cover 16 is glass while the substrate wafer 14 is silicon.

FIG. 1D shows a portion (represented by dotted area D in FIG. 1C) of the cover 16 and underlying MEMS device wafer 12, and FIG. 1E shows a cross-section (represented by dotted area E in FIGS. 1A and 1B) of the device wafer 12, the substrate wafer 14, and the cover 16. The cover 16 includes sections of exposed glass 18 and sections of glass covered by a metal layer 20. The sections 16, 18 may be of any configuration and location. The device wafer 12 includes perforations 22 extending through the device wafer 12. As can best be seen in FIG. 1D, the perforations 22 are located under the sections of exposed glass 18 so as to minimize the area of exposed glass section 18 that overlaps the device wafer 12. The width 24 of the perforations 22 is larger than the width of the exposed glass section 18. The distance 26 between adjacent perforations 22 is as small as possible, and the length 28 is as large as possible, consistent with the device stiffness required for the intended use.

FIG. 2 is a flow diagram of a method 30 according to the present invention. At a block 32, metal layers are applied to a glass cover as needed for the intended use of the cover and MEMS device. At a block 34, the device wafer is perforated at locations corresponding to areas of exposed glass on the glass cover when the glass cover is bonded to a substrate wafer. At a block 36, the device wafer is bonded to the substrate wafer. At a block 38, the glass cover is anodically bonded to the device wafer. In an alternate embodiment, the glass cover is anodically bonded to the substrate wafer.

While the preferred embodiment of the invention has been illustrated and described, as noted above, many changes can be made without departing from the spirit and scope of the invention. Accordingly, the scope of the invention is not limited by the disclosure of the preferred embodiment. Instead, the invention should be determined entirely by reference to the claims that follow.

1. A device comprising:
a substrate wafer;
a glass cover including at least one area of exposed glass and at least one area of metal-covered glass;
a microelectromechanical systems (MEMS) device wafer mounted to the substrate wafer, the device wafer including at least one perforation through the device wafer;
wherein the at least one perforation corresponds to a location of the at least one area of exposed glass when the glass cover is attached to one of the device wafer and the substrate wafer.

2. The device of claim 1 wherein the at least one perforation is wider than a width of a corresponding area of exposed glass.

3. The device of claim 1, wherein the at least one perforation has a length such that the area of exposed glass overlapping the area of the device wafer is minimized, and such that a structural stiffness of the device wafer is consistent with the structural stiffness required by an intended use of the device wafer.

4. The device of claim 1, wherein the at least one perforation includes two perforations, and the distance between the two perforations is such that the area of exposed glass overlapping the area of the device wafer is minimized, and such that a structural stiffness of the device wafer is consistent with the structural stiffness required by an intended use of the device wafer.

5. The device of claim 1, wherein the glass cover is bonded to the device wafer on a same horizontal plane as a location of a mechanism of the device wafer.

5. (canceled)

6. (canceled)

7. (canceled)

8. (canceled)

9. (canceled)

10. (canceled)

11. (canceled)

12. (canceled)
